(19) United States
(12) Patent Application Publication
(10) Pub. No.: US 2025/0062292 A1
(43) Pub. Date: Feb. 20, 2025

(54) ELECTRONIC DEVICE

(71) Applicant: CARUX TECHNOLOGY PTE. LTD., SINGAPORE (SG)

(72) Inventors: Chueh-Yuan Nien, Tainan (TW); Chao-Chin Sung, Tainan (TW)

(73) Assignee: CARUX TECHNOLOGY PTE. LTD., SINGAPORE (SG)

(21) Appl. No.: 18/769,429

(22) Filed: Jul. 11, 2024

(30) Foreign Application Priority Data
Aug. 16, 2023 (CN) 202311033253.4

(51) Int. Cl. H01L 25/075

(52) U.S. Cl. CPC H01L 25/0753

(57) ABSTRACT

An electronic device includes a substrate, first and second light-emitting units disposed on the substrate, first and second driving circuits disposed on the substrate, and a conductive layer. The first driving circuit includes a first transistor for driving the first light-emitting unit. The second driving circuit includes a second transistor for driving the second light-emitting unit. The conductive layer is disposed between the substrate and the first light-emitting unit and between the substrate and the second light-emitting unit, and includes a first portion and a second portion connected to the first portion, where the first transistor includes a first semiconductor layer, the second transistor includes a second semiconductor layer, and in a normal direction of the substrate, the first portion at least partially overlaps the first semiconductor layer, and the second portion at least partially overlaps the second semiconductor layer. A yield of the electronic device can be improved.

### CROSS-REFERENCE TO RELATED APPLICATION

This application claims the priority benefit of China application serial no. 202311033253.4, filed on Aug. 16, 2023. The entirety of the above-mentioned patent application is hereby incorporated by reference herein and made a part of this specification.

### BACKGROUND

### Technical Field

The disclosure relates to an electronic device; more particularly, the disclosure relates to an electronic device including light-emitting elements.

### Description of Related Art

In the course of electronic device fabrication, pre-existing elements and traces are susceptible to defects arising from the influence of subsequent processes, thus resulting in a comparatively diminished yield in the finished electronic device.

### SUMMARY

This disclosure provides an electronic device with an improved yield.

In an embodiment of the disclosure, an electronic device including a substrate, a first light-emitting unit, a second light-emitting unit, a first driving circuit, a second driving circuit, and a conductive layer is provided. The first light-emitting unit and the second light-emitting unit are disposed on the substrate. The first driving circuit is disposed on the substrate and includes a first transistor configured to drive the first light-emitting unit. The second driving circuit is disposed on the substrate and includes a second transistor configured to drive the second light-emitting unit. The conductive layer is disposed between the substrate and the first light-emitting unit and between the substrate and the second light-emitting unit and includes a first portion and a second portion connected to the first portion. Here, the first transistor includes a first semiconductor layer, the second transistor includes a second semiconductor layer, and in a normal direction of the substrate, the first portion at least partially overlaps the first semiconductor layer, and the second portion at least partially overlaps the second semiconductor layer.

In another embodiment of the disclosure, an electronic device including a substrate, a first light-emitting unit, a first driving circuit, and a conductive layer is provided. The substrate includes a plurality of pixel regions. The first light-emitting unit is disposed on the substrate and located in one of the pixel regions. The first driving circuit is disposed on the substrate and configured to drive the first light-emitting unit, where the first driving circuit is located in the one of the pixel regions. The conductive layer is disposed between the substrate and the first light-emitting unit, where at least one portion of the conductive layer is located in the one of the pixel regions. In a top view of the electronic device, the at least one portion of the conductive layer located in the one of the pixel regions occupies a first area, and a ratio of the first area to a second area occupied by the pixel regions is greater than or equal to 50% and less than or equal to 100%.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view illustrating an electronic device according to an embodiment of the disclosure.

FIG. 1B is a schematic enlarged view illustrating pixel regions in the electronic device depicted in FIG. 1A.

FIG. 1C is a schematic enlarged view illustrating a conductive layer in the pixel regions in the electronic device depicted in FIG. 1A.

FIG. 1D is a schematic view illustrating an area occupied by the pixel regions in the electronic device depicted in FIG. 1A.

FIG. 1E is a schematic view illustrating an area occupied by a switch transistor in the electronic device depicted in FIG. 1A.

FIG. 1F is a schematic view illustrating an area occupied by a driving transistor in the electronic device depicted in FIG. 1A.

FIG. 1G is a schematic view illustrating an area occupied by a storage capacitor in the electronic device depicted in FIG. 1A.

FIG. 1H is a schematic view illustrating an area occupied by a signal line in the electronic device depicted in FIG. 1A.

FIG. 2A is a schematic top view illustrating an electronic device according to another embodiment of the disclosure.

FIG. 2B is a schematic partial cross-sectional view taken along a sectional line A-A′ depicted in FIG. 2A.

FIG. 3A is a schematic partial cross-sectional view illustrating an arrangement relationship between a first semiconductor layer and a conductive layer in an electronic device according to a first embodiment of the disclosure.

FIG. 3B is a schematic partial cross-sectional view illustrating an arrangement relationship between a first semiconductor layer and a conductive layer in an electronic device according to a second embodiment of the disclosure.

FIG. 3C is a schematic partial cross-sectional view illustrating an arrangement relationship between a first semiconductor layer and a conductive layer in an electronic device according to a third embodiment of the disclosure.

FIG. 3D is a schematic partial cross-sectional view illustrating an arrangement relationship between a first semiconductor layer and a conductive layer in an electronic device according to a fourth embodiment of the disclosure.

FIG. 3E is a schematic partial cross-sectional view illustrating an arrangement relationship between a first semiconductor layer and a conductive layer in an electronic device according to a fifth embodiment of the disclosure.

FIG. 4A is a schematic partial cross-sectional view illustrating an arrangement relationship between a storage capacitor and the conductive layer in the electronic device according to the first embodiment of the disclosure.

FIG. 4B is a schematic partial cross-sectional view illustrating an arrangement relationship between a storage capacitor and the conductive layer in the electronic device according to the second embodiment of the disclosure.

FIG. 4C is a schematic partial cross-sectional view illustrating an arrangement relationship between a storage capacitor and the conductive layer in the electronic device according to the third embodiment of the disclosure.

FIG. 4D is a schematic partial cross-sectional view illustrating an arrangement relationship between a storage capacitor and the conductive layer in the electronic device according to the fourth embodiment of the disclosure.

FIG. 4E is a schematic partial cross-sectional view illustrating an arrangement relationship between a storage capacitor and the conductive layer in the electronic device according to the fifth embodiment of the disclosure.

FIG. 5A is a schematic partial cross-sectional view illustrating an arrangement relationship between a signal line and the conductive layer in the electronic device according to the first embodiment of the disclosure.

FIG. 5B is a schematic partial cross-sectional view illustrating an arrangement relationship between a signal line and the conductive layer in the electronic device according to the second embodiment of the disclosure.

FIG. 5C is a schematic partial cross-sectional view illustrating an arrangement relationship between a signal line and the conductive layer in the electronic device according to the third embodiment of the disclosure.

FIG. 5D is a schematic partial cross-sectional view illustrating an arrangement relationship between a signal line and the conductive layer in the electronic device according to the fourth embodiment of the disclosure.

FIG. 5E is a schematic partial cross-sectional view illustrating an arrangement relationship between a signal line and the conductive layer in the electronic device according to fifth first embodiment of the disclosure.

### DETAILED DESCRIPTION OF DISCLOSED EMBODIMENTS

Reference will now be made in detail to the exemplary embodiments of the disclosure, and examples of the exemplary embodiments are illustrated in the accompanying drawings. Whenever possible, the same reference numbers are used in the drawings and descriptions to indicate the same or similar parts.

The disclosure may be understood with reference to the following detailed description with the drawings. Note that for clarity of description and ease of understanding, the drawings of the disclosure show a part of an electronic device, and certain components in the drawings may not be drawn to scale. In addition, the number and size of each device shown in the drawings simply serve for exemplifying instead of limiting the scope of the disclosure.

Certain terminologies are used throughout the description and the appended claims to refer to specific components. As to be understood by those skilled in the art, electronic device manufacturers may refer to a component by different names. Herein, it is not intended to distinguish between components that have different names instead of different functions. In the following description and claims, terminologies such as “include,” “comprise,” and “have” are used in an open-ended manner, and thus should be interpreted as “including, but not limited to”. Therefore, the terminologies “include,” “comprise,” and/or “have” used in the description of the disclosure denote the presence of corresponding features, areas, steps, operations, and/or components but are not limited to the presence of one or more corresponding features, areas, steps, operations, and/or components.

In this disclosure, directional terminologies, such as “top,” “bottom,” “front,” “back,” and so on, are used with reference to the orientation of the accompanying drawings. As such, the directional terminologies are used for purposes of illustration and are in no way limiting. In the accompanying drawings, each drawing shows the general features of the methods, structures and/or materials adopted in a specific embodiment. However, the drawings should not be construed as defining or limiting the scope or nature covered by the embodiments. For instance, for clarity, the relative size, thickness, and position of each layer, area, and/or structure may be reduced or enlarged.

When a corresponding element (such as a film layer or an area) is referred to as being “on another element,” the element may be directly on the other element or there may be another element between the two. On the other hand, when an element is referred to as being “directly on another element,” there is no element between the two. Also, when an element is referred to as being “on another element,” the two have a top-down relationship in the top view direction, and the element may be above or below the other element, and the top-down relationship depends on the orientation of the device.

The terminology “about,” “substantially,” or “approximately” is generally interpreted as being within 10% of a given value or range, or interpreted as being within 5%, 3%, 2%, 1%, or 0.5% of a given value or range.

In the context of the specification and claims, the utilization of ordinal indicators like “first,” “second,” and so forth, in relation to modifying elements, does not inherently suggest or signify the presence of any preceding ordinal numbers for said elements. Nor do these indicators imply a sequential relationship between elements, either in terms of their assembly or within the manufacturing process. The primary purpose of these ordinal indicators is to unambiguously differentiate an element bearing a specific name from another element bearing the same name. It should be noted that while the indicators employed in the claims and specification might diverge, the ordinal assignment can also differ; consequently, an element indicated as being the “first” in the specification might correspond to the “second” element as indicated in the claims.

Note that in the following embodiments, the technical features provided in several different embodiments may be replaced, reorganized, and mixed without departing from the spirit of the disclosure so as to complete other embodiments. The technical features of the embodiments may be mixed and matched arbitrarily as long as they do not violate the spirit of the disclosure or conflict with each other.

The electrical connection or coupling described in this disclosure may refer to direct connection or indirect connection. In the case of direct connection, the endpoints of the elements on the two circuits are directly connected or are connected to each other by a conductor segment. In the case of indirect connection, between the end points of the elements on the two circuits there are switches, diodes, capacitors, inductances, other suitable elements, or a combination of the above-mentioned elements, which should however not be construed as a limitation in the disclosure.

In this disclosure, measurement of length, width, thickness, height, width, and area may be done by applying an optical microscope (OM), and the thickness may be measured by obtaining a cross-sectional image of a to-be-measured element through applying a scanning electron microscope (SEM), which should however not be construed as a limitation in the disclosure. In addition, certain errors between any two values or directions for comparison may be acceptable. If a first value is equal to a second value, it indicates that a margin of error of about 10% may exist between the first and second values. If a first direction is perpendicular to a second direction, an angle difference between the first direction and the second direction may be between 80 degrees and 100 degrees; if the first direction is parallel to the second direction, an angle difference between the first direction and the second direction may be between 0 degrees and 10 degrees.

The electronic device provided in one or more embodiments of the disclosure may include a light-emitting device, a display device, a sensing device, an antenna device, or a splicing device, which should however not be interpreted as a limitation in the disclosure. The electronic device may include a bendable or flexible electronic device, and the electronic device may, for instance, include a liquid crystal layer or a light-emitting diode (LED). The electronic device may include an electronic element. The electronic element may include a passive element and an active element, such as a capacitor, a resistor, an inductor, a variable capacitor, a filter, a diode, a transistor, a sensor, a micro-electro mechanical system (MEMS), a liquid crystal chip, and so forth, which should however not be interpreted as a limitation in the disclosure. The diode may include the LED or a photodiode. The LED may, for instance, include an organic light-emitting diode (OLED), a mini LED, a micro LED, a quantum dot LED, fluorescence, phosphor, other appropriate materials, or a combination thereof, which should however not be interpreted as a limitation in the disclosure. The sensor may, for instance, include a capacitive sensor, an optical sensor, an electromagnetic sensor, a fingerprint sensor (FPS), a touch sensor, an antenna, a pen sensor, and so on, which should however not be interpreted as a limitation in the disclosure.

Exemplary embodiments of the disclosure are provided below, where the electronic device is described as the light-emitting device, and the same reference numbers are used in the figures and descriptions to represent the same or similar parts.

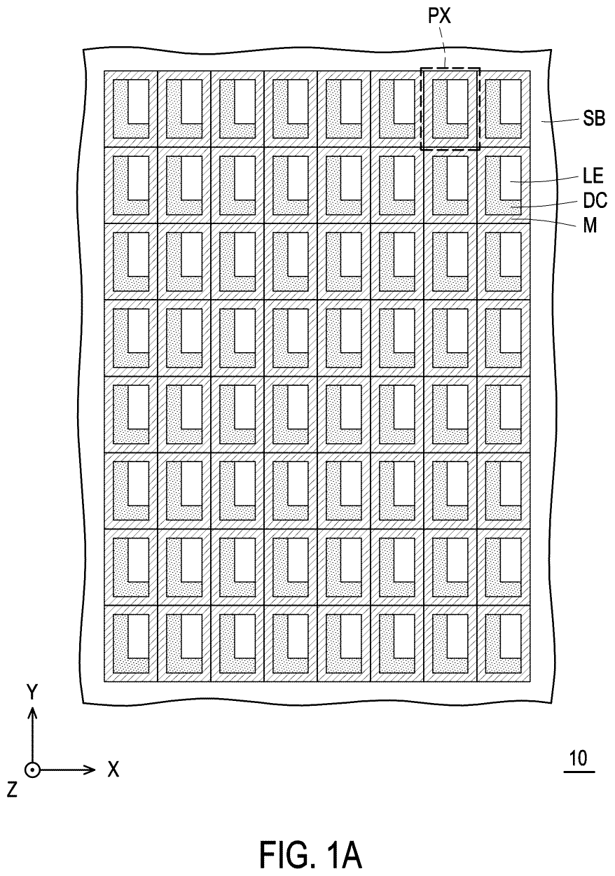

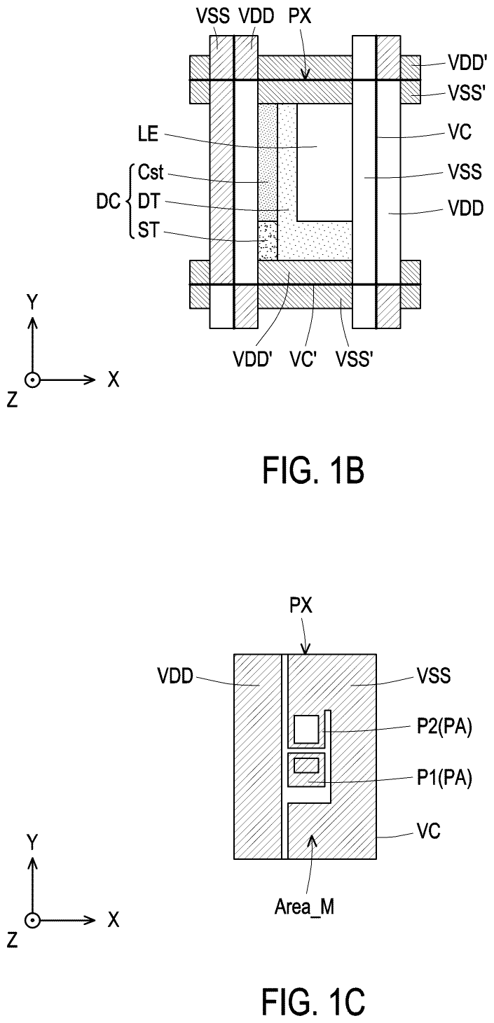

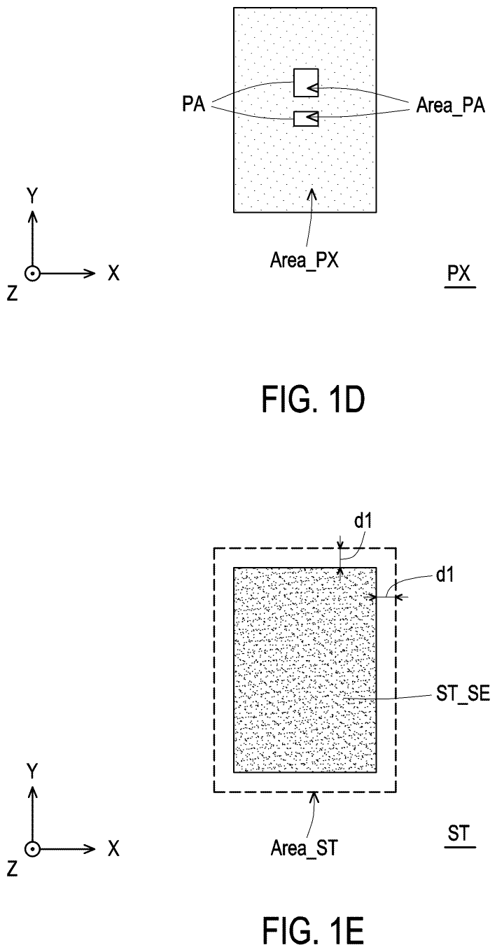

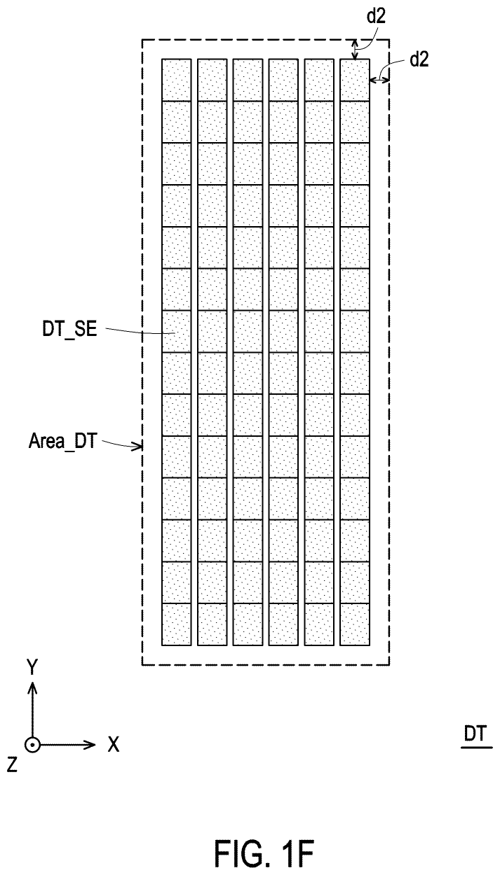

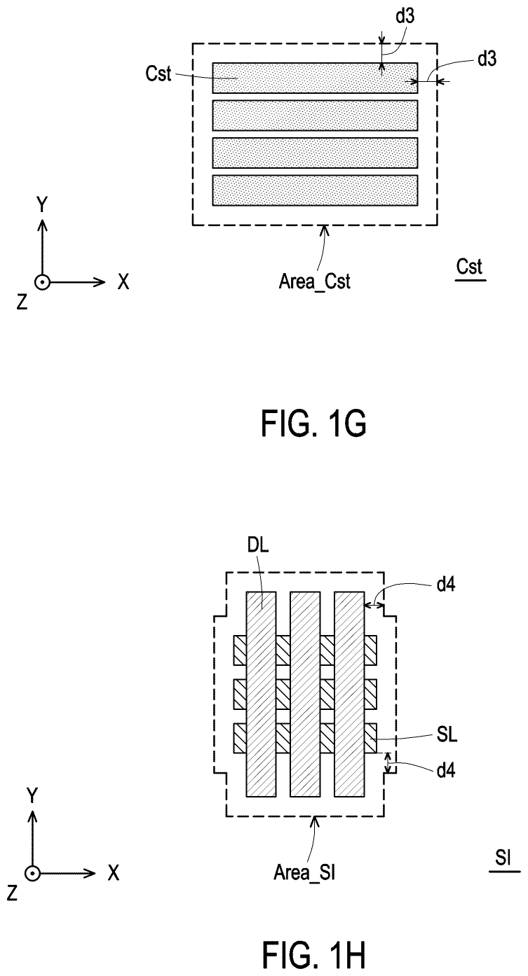

FIG. 1A is a schematic top view illustrating an electronic device according to an embodiment of the disclosure. FIG. 1B is a schematic enlarged view illustrating pixel regions in the electronic device depicted in FIG. 1A. FIG. 1C is a schematic enlarged view illustrating a conductive layer in the pixel regions in the electronic device depicted in FIG. 1A.

With reference to FIG. 1A and FIG. 1B, an electronic device 10 provided in this embodiment includes a substrate SB, a light-emitting unit LE, a driving circuit DC, and a conductive layer M. From another perspective, the electronic device 10 includes a plurality of pixel regions PX, where the pixel regions PX are arranged in an array. Specifically, the pixel regions PX may be arranged along a second direction X and/or a first direction Y, which should however not be construed as a limitation in the disclosure.

A material of the substrate SB may include, for instance, glass, plastic, or a combination thereof. For instance, the material of the substrate SB may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), other suitable materials, or a combination of the above materials, which should however not be construed as a limitation in the disclosure.

The light-emitting unit LE is, for instance, disposed on the substrate SB, where the light-emitting unit LE is located in one of the pixel regions PX. The light-emitting unit LE may include, for instance, a mini-LED, an OLED, a micro-LED, or a QDLED. In this embodiment, the light-emitting unit LE includes the mini-LED, which should however not be construed as a limitation in the disclosure.

The driving circuit DC is, for instance, disposed on the substrate SB, where the driving circuit DC is located in one of the pixel regions PX. In some embodiments, the driving circuit DC is coupled to the light-emitting unit LE, so as to be configured to drive the light-emitting unit LE. In this embodiment, as shown in FIG. 1B, the driving circuit DC includes a switch transistor ST, a driving transistor DT, and a storage capacitor Cst, which should however not be construed as a limitation in the disclosure.

In some embodiments, the driving circuit DC and the light-emitting unit LE may be coupled in a manner described below, which should however not be construed as a limitation in the disclosure.

A control terminal of the switch transistor ST (not shown) may, for instance, be coupled to a scan line (not shown), a first terminal of the switch transistor ST (not shown) may, for instance, be coupled to a data line (not shown), a second terminal of the switch transistor ST (not shown) may, for instance, be coupled to the storage capacitor Cst, a control terminal of the driving transistor DT (not shown) may, for instance, be coupled to the storage capacitor Cst, a first terminal of the driving transistor DT (not shown) may, for instance, be coupled to a power line (not shown), and a second terminal of the driving transistor DT (not shown) may, for instance, be coupled to the light-emitting unit LE.

In view of the above, when the control terminal of the switch transistor ST receives a corresponding scan signal from the scan line and accordingly turns on the switch transistor ST, a data signal from the data line may reach the storage capacitor Cst through the first and second terminals of the switch transistor ST and is stored in the storage capacitor Cst. Subsequently, when the control terminal of the driving transistor DT receives a corresponding data signal from the storage capacitor Cst and turns on the switch transistor ST, a corresponding driving current may be generated according to a power voltage received by the first terminal of the driving transistor DT from the power line, and the driving current flows to the light-emitting unit LE through the second terminal of the driving transistor DT, thereby driving the light-emitting unit LE.

In some embodiments, the number of the switch transistors ST in one of the pixel regions PX may be one, the number of the driving transistors DT in one of the pixel regions PX may be plural, and the number of the storage capacitors Cst in one of the pixel regions PX may be plural, which should however not be construed as a limitation in the disclosure.

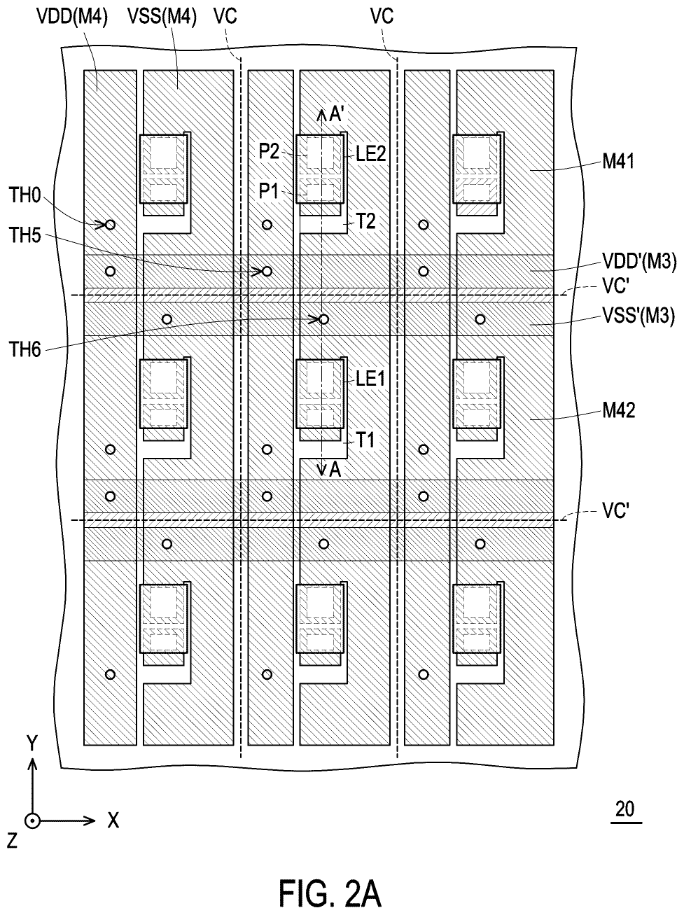

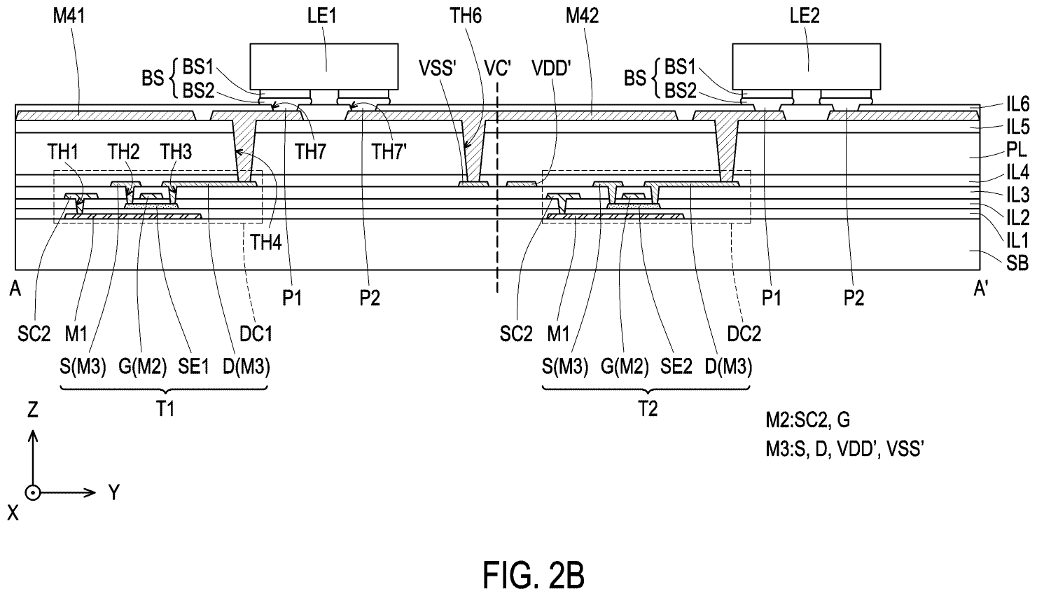

The conductive layer M is, for instance, disposed on the substrate SB, where at least one portion of the conductive layer M is located in one of the pixel regions PX. According to this embodiment, in a normal direction of the substrate SB, the conductive layer M is disposed between the substrate SB and the light-emitting unit LE, which should however not be construed as a limitation in the disclosure. As shown in FIG. 1C, the conductive layer M may include a pad pattern P1, a pad pattern P2, a first power line VDD, and a second power line VSS, where the pad patterns P1 and P2 may be electrically connected to the light-emitting unit LE, for instance, and the first power line VDD and the second power line VSS may extend along the first direction Y, for instance. It is worth noting that in this disclosure, a range of the pad patterns P1 and P2 is defined as a portion of the conductive layer M that is exposed by through holes (such as the through holes TH7 and TH7′ in FIG. 2B).

In this embodiment, the electronic device 10 further includes a third power line VDD′ and a fourth power line VSS' extending along the second direction X. The pixel regions PX are, for instance, defined by the first power line VDD and the second power line VSS extending along the first direction Y and the third power line VDD and the fourth power line VSS′ extending along the second direction X. Specifically, the pixel regions PX are surrounded by a boundary VC between the first power line VDD and the second power line VSS adjacent to each other and a boundary VC′ between the third power line VDD′ and the fourth power line VSS′ adjacent to each other. More specifically, there is a gap between the first power line VDD and the second power line VSS that are adjacent to each other but correspond to different pixel regions PX, so as to prevent an electrical connection between the first power line VDD and the second power line VSS, and a central line of the gap between the first power line VDD and the second power line VSS may be defined as the boundary VC. Similarly, there is another gap between the third power line VDD′ and the fourth power line VSS′ that are adjacent to each other but correspond to different pixel regions PX, so as to prevent an electrical connection between the third power line VDD′ and the fourth power line VSS′, and a central line of the gap between the third power line VDD′ and the fourth power line may be defined as the boundary VC′. For clearly illustrating the arrangement of various components, a portion of the conductive layer M is omitted from FIG. 1A and FIG. 1B, thus exposing the driving circuit DC. In some embodiments, an area occupied by the first power line VDD and the second power line VSS may be increased to substantially overlap the light-emitting unit LE and the driving circuit DC shown in FIG. 1B.

FIG. 1D is a schematic view illustrating an area occupied by the pixel regions in the electronic device depicted in FIG. 1A. FIG. 1E is a schematic view illustrating an area occupied by the switch transistor in the electronic device depicted in FIG. 1A. FIG. 1F is a schematic view illustrating an area occupied by the driving transistor in the electronic device depicted in FIG. 1A. FIG. 1G is a schematic view illustrating an area occupied by the storage capacitor in the electronic device depicted in FIG. 1A. FIG. 1H is a schematic view illustrating an area occupied by the signal line in the electronic device depicted in FIG. 1A.

In an embodiment illustrated in FIG. 1C, at least one portion of the conductive layer M located in one of the pixel regions PX occupies a first area Area_M; in an embodiment illustrated in FIG. 1D, one of the pixel regions PX occupies a second area Area_PX. In this embodiment, a ratio of the first area Area_M occupied by the conductive layer M in the pixel regions PX to the second area Area_PX occupied by the one of the pixel regions PX is greater than or equal to 50% and less than or equal to 100% (50%≤Area_M/Area_PX≤100%). It is worth noting that the second area Area_PX occupied by the one of the pixel regions PX does not include a pad area Area_PA (occupied by the pad pattern P1 and the pad pattern P2 in FIG. 1C).

In an embodiment illustrated in FIG. 1E, the switch transistor ST occupies a third area Area_ST. It is worth noting that the third area Area_ST occupied by the switch transistor ST may be defined, for instance, by defining a specific distance d1 extending outward from an edge of the semiconductor layer SE1 of the switch transistor ST. For instance, the third area Area_ST occupied by the switch transistor ST may be defined by defining the specific distance d1 extending in the second direction X and/or the first direction Y from the edge of the semiconductor layer SE1 of the switch transistor ST, where the specific distance d1 is approximately 10 micrometers, which should however not be construed as a limitation in the disclosure. In other embodiments, the number of the switch transistors ST in one of the pixel regions PX may be plural, and the third area Area_ST occupied by the switch transistors ST may be the sum of the individual third areas defined by each switch transistor ST in the aforementioned manner, but if some of the third areas of the switch transistors ST overlap, the overlapping area is not counted. In some embodiments, a semiconductor layer ST_SE of the switch transistor ST and the conductive layer M are at least partially overlapped in the normal direction Z of the substrate SB. In this embodiment, a ratio of the overlapping area between the semiconductor layer ST_SE of the switch transistor ST and the conductive layer M in the normal direction Z of the substrate SB to the third area Area_ST occupied by the switch transistors ST is greater than or equal to 50% and less than or equal to 100% (50% the overlapping area/Area_ST≤100%).

In an embodiment illustrated in FIG. 1F, the driving transistor DT occupies a fourth area Area_DT. It is worth noting that a method of calculating the fourth area Area_DT occupied by the driving transistor DT is similar to the method of calculating the third area Area_ST occupied by the switch transistor ST, and both areas are defined by defining a specific distance (such as a distance d2) extending from the edge of the semiconductor layer, where the specific distance d2 is approximately 10 micrometers, which should however not be construed as a limitation in the disclosure. When it includes the number of the driving transistors DT is plural, the method of calculating the fourth area Area_DT is the same as the method of calculating the third area Area_ST when the number of the switch transistors ST is also plural, which will not be further elaborated here. In some embodiments, the semiconductor layer DT_SE of the driving transistor DT and the conductive layer M at least partially overlap in the normal direction Z of the substrate SB. In this embodiment, a ratio of the overlapping area between the semiconductor layer DT_SE of the driving transistor DT and the conductive layer M in the normal direction Z of the substrate SB to the fourth area Area_DT occupied by the driving transistors DT is greater than or equal to 50% and less than or equal to 100% (50%≤the overlapping area/Area_DT≤100%).

A material of the semiconductor layer ST_SE and the semiconductor layer DT_SE may include, for instance, low temperature polysilicon (LTPS), metal oxide, amorphous silicon (a-Si), or a combination thereof, which should however not be construed as a limitation in the disclosure. For instance, the material of the semiconductor layer SE may include but is not limited to a-Si, polysilicon, germanium, a compound semiconductor (such as gallium nitride, silicon carbide, gallium arsenide, gallium phosphide, indium phosphide, indium arsenide, and/or indium antimonide), an alloy semiconductor (such as SiGe alloy, GaAsP alloy, AlInAs alloy, AlGaAs alloy, GaInAs alloy, GaInP alloy, GaInAsP alloy), or a combination thereof. The material of the semiconductor layer SE may also include but is not limited to metal oxide, such as indium gallium zinc oxide (IGZO), indium zinc oxide (IZO), indium gallium zinc tin oxide (IGZTO), an organic semiconductor containing polycyclic aromatic compounds, or a combination thereof.

In the embodiment illustrated in FIG. 1G, the storage capacitor Cst occupies a fifth area Area_Cst. It is worth noting that the fifth area Area_Cst occupied by the storage capacitor Cst may be defined, for instance, by defining a specific distance d3 extending outward from an edge of the storage capacitor Cst, where the specific distance d3 is approximately 10 micrometers, which should however not be construed as a limitation in the disclosure. Similar to the method of calculating the third area Area_ST, when the storage capacitor Cst is a combination of a plurality of the storage capacitors Cst, the fifth area Area_Cst is the sum of the fifth areas occupied by individual storage capacitors Cst, but if some of the fifth areas occupied by the storage capacitors Cst overlap, the overlapping area is not counted. In the fifth area Area_Cst, the distance between adjacent storage capacitors Cst is less than the specific distance d3. For instance, as shown in FIG. 1G, when the storage capacitors Cst are closely arranged (the distance between the storage capacitors Cst is less than the distance d3), the fifth area Area_Cst may be defined by defining the specific distance d3 extending in the second direction X and/or the first direction Y from the edge of the outermost storage capacitor Cst. In some embodiments, the storage capacitors Cst and the conductive layer M at least partially overlap in the normal direction Z of the substrate SB. In this embodiment, a ratio of the overlapping area between the storage capacitors Cst and the conductive layer M in the normal direction Z of the substrate SB is greater than or equal to 50% and less than or equal to 100% of the fifth area Area_Cst occupied by the storage capacitors Cst (50%≤the overlapping area/Area_Cst≤100%).

In some embodiments, the electronic device 10 further includes a signal line SI, where the signal line SI may include scan lines, data lines, power lines, and other suitable signal lines that are located in a layer different from the conductive layer M mentioned above, which should however not be construed as a limitation in the disclosure. In the embodiment shown in FIG. 1H, the signal line SI occupies a sixth area Area_SI. It is worth noting that the sixth area Area_SI occupied by the signal line SI may be defined, for instance, by defining a specific distance d4 extending outward from an edge of the signal line SI, where the specific distance d4 is approximately 10 micrometers, which should however not be construed as a limitation in the disclosure. Similar to the method of calculating the third area Area_ST, when a plurality of the signal lines SI are closely arranged (the distance between the signal lines SI is less than the distance d4), the sixth area Area_SI is the sum of the sixth areas occupied by the individual signal lines SI, but if some of the sixth areas occupied by the signal lines SI overlap, the overlapping area is not counted. For instance, as shown in FIG. 1H, when the signal lines SI are closely arranged, the sixth areas Area_SI occupied by the signal lines SI may be defined by defining a specific distance d4 extending outward from the edge of the outermost data line in the second direction X and/or from the edge of the outermost scan line in the first direction Y In some embodiments, the signal lines SI and the conductive layer M at least partially overlap in the normal direction Z of the substrate SB. In this embodiment, a ratio of the overlapping area between the signal lines SI and the conductive layer M in the normal direction Z of the substrate SB to the sixth areas Area_SI occupied by the signal lines SI is greater than or equal to 50% and less than or equal to 100% (50% the overlapping area/Area_SI≤100%).

In light of the foregoing, by making the ratio of the first area Area_M occupied by the conductive layer M disposed in the pixel regions PX to the second area Area_PX occupied by the pixel regions PX greater than or equal to 50% and less than or equal to 100%, the components that have been formed in the pixel regions PX may be at least partially shielded by the conductive layer M in the process of forming the remaining components, thereby reducing the possibility of defect generation. Accordingly, the electronic device 10 provided in this embodiment may have an improved yield.

Besides, in this embodiment, as shown in FIG. 1E to FIG. 1H, the third area Area_ST occupied by the switch transistor ST, the fourth area Area_DT occupied by the driving transistor DT, the fifth area Area_Cst occupied by the storage capacitor Cst, and/or the sixth area Area_SI occupied by the signal line SI have the aforementioned relationship with the first area Area_M occupied by the conductive layer M disposed in the pixel regions PX. This allows the switch transistor ST, the driving transistor DT, the storage capacitor Cst, and/or the signal line SI that have been formed in the pixel regions PX to be shielded by the conductive layer M in the process of forming the remaining components, thereby reducing the possibility of defect generation. Accordingly, the electronic device 10 provided in this embodiment may have an improved yield.

FIG. 2A is a schematic top view illustrating an electronic device according to another embodiment of the disclosure. FIG. 2B is a schematic partial cross-sectional view taken along a sectional line A-A′ depicted in FIG. 2A. It should be noted that the reference numbers and some content provided in the embodiments shown in FIG. 2A and FIG. 2B may be derived from the reference numbers and some content provided in the embodiments shown in FIG. 1A to FIG. 1H, where the same or similar reference numbers serve to represent the same or similar components, and the description of the same technical content is omitted.

With reference to FIG. 2A and FIG. 2B, an electronic device 20 provided in this embodiment includes the substrate SB, a first light-emitting unit LE1, a second light-emitting unit LE2, a first driving circuit DC1, a second driving circuit DC2, and a conductive layer M4.

The description of the substrate SB may be referred to as the description provided in the previous embodiment and thus will no longer be provided hereinafter.

The first light-emitting unit LE1 and the second light-emitting unit LE2 are, for instance, disposed on the substrate SB. The description of the first light-emitting unit LE1 and the second light-emitting unit LE2 may be referred to as the description provided in the previous embodiment and thus will no longer be provided hereinafter.

The first driving circuit DC1 is, for instance, disposed on the substrate SB and includes a first transistor T1, where the first transistor T1 is configured to drive the first light-emitting unit LE1. In this embodiment, the first transistor T1 includes a first semiconductor layer SE1, where the first semiconductor layer SE1 may include the semiconductor layer provided in the previous embodiment, which will not be further described hereinafter. It is worth noting that although it is the driving transistor shown in FIG. 2B, the first transistor T1 in the electronic device 20 provided in this embodiment also includes a switch transistor. The description of the switch transistor and the driving transistor may be referred to as the description provided in the previous embodiment and thus will no longer be provided hereinafter.

Similarly, the second driving circuit DC2 is, for instance, disposed on the substrate SB and includes a second transistor T2, where the second transistor T2 is configured to drive the second light-emitting unit LE2. In this embodiment, the second driving circuit DC2 has the same or similar components as those of the first driving circuit DC1; that is, the second transistor T2 also includes a switch transistor and a driving transistor. The description of the switch transistor and the driving transistor may be referred to as the description provided in the previous embodiment and thus will no longer be provided hereinafter. In some embodiments, the second transistor T2 also includes a second semiconductor layer SE2, where the second semiconductor layer SE2 may include the semiconductor layer provided in the previous embodiment, which will not be further described hereinafter.

The conductive layer M4 is, for instance, disposed between the substrate SB and the first light-emitting unit LE1 and between the substrate SB and the second light-emitting unit LE2, and includes a first portion M41 and a second portion M42 connected to the first portion M41. The first portion M41 may be, for instance, a portion of the conductive layer M4 located in the pixel regions PX of the first transistor T1, while the second portion M42 may be a portion of the conductive layer M4 located in the pixel regions PX of the second transistor T2. In this embodiment, in the normal direction Z of the substrate SB, the conductive layer M4 is located between the first semiconductor layer SE1 and the first light-emitting unit LE1 and between the second semiconductor layer SE2 and the second light-emitting unit LE2, which should however not be construed as a limitation in the disclosure. Additionally, in this embodiment, the conductive layer M4 is the uppermost conductive layer in the electronic device 20 except for a bonding structure BS, which should however not be construed as a limitation in the disclosure. In some embodiments, in the normal direction Z of the substrate SB, the first portion M41 at least partially overlaps the first semiconductor layer SE1, and the second portion M42 at least partially overlaps the second semiconductor layer SE2. In this embodiment, the first semiconductor layer SE1 completely overlaps the first portion M41 of the conductive layer M4, and the second semiconductor layer SE2 also completely overlaps the second portion M42 of the conductive layer M4, which should however not be construed as a limitation in the disclosure.

In summary, the conductive layer M4 includes the first portion M41 and the second portion M42 that cross over at least two pixel regions PX, where the first portion M41 and the second portion M42 are connected to each other, and each of the first portion M41 and the second portion M42 at least partially overlaps the first semiconductor layer SE1 of the first transistor T1 and the second semiconductor layer SE2 of the second transistor T2.

Accordingly, in this embodiment, the conductive layer M4 may serve to at least shield the first semiconductor layer SE1 and the second semiconductor layer SE2 that have been formed in the process of forming the electronic device 20, thereby reducing the possibility of defects generated in the first semiconductor layer SE1 and the second semiconductor layer SE2 during the process of forming other components. Therefore, the electronic device 20 in this embodiment may have an improved yield.

In some embodiments, the electronic device 20 further includes a conductive layer M1, an insulating layer IL1, an insulating layer IL2, a conductive layer M2, an insulating layer IL3, a conductive layer M3, an insulating layer IL4, a planarization layer PL, an insulating layer IL5, an insulating layer IL6, and the bonding structure BS.

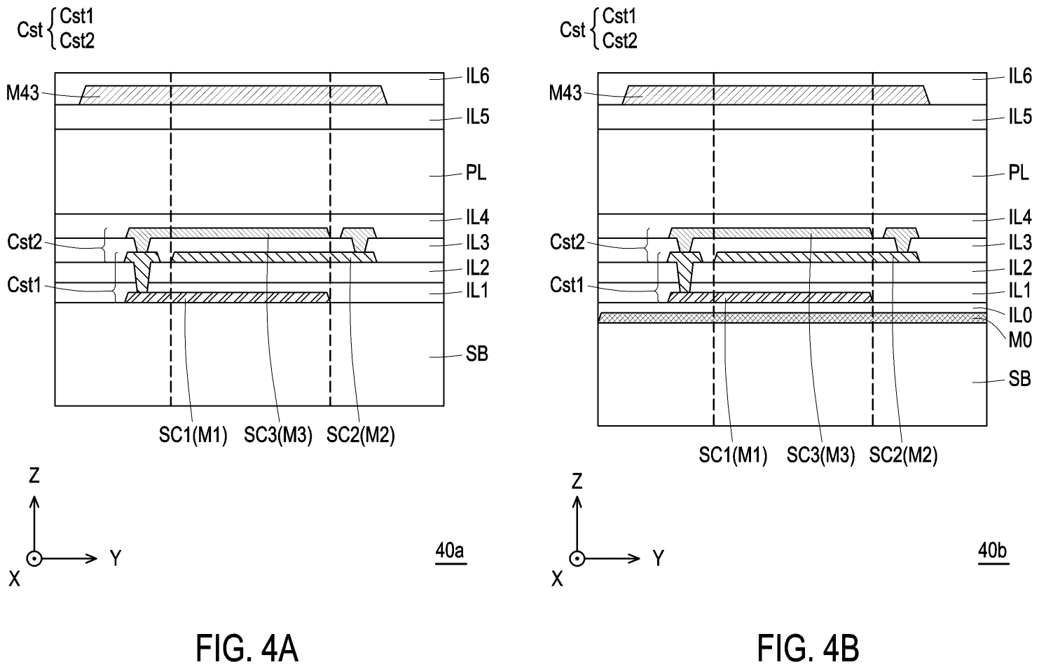

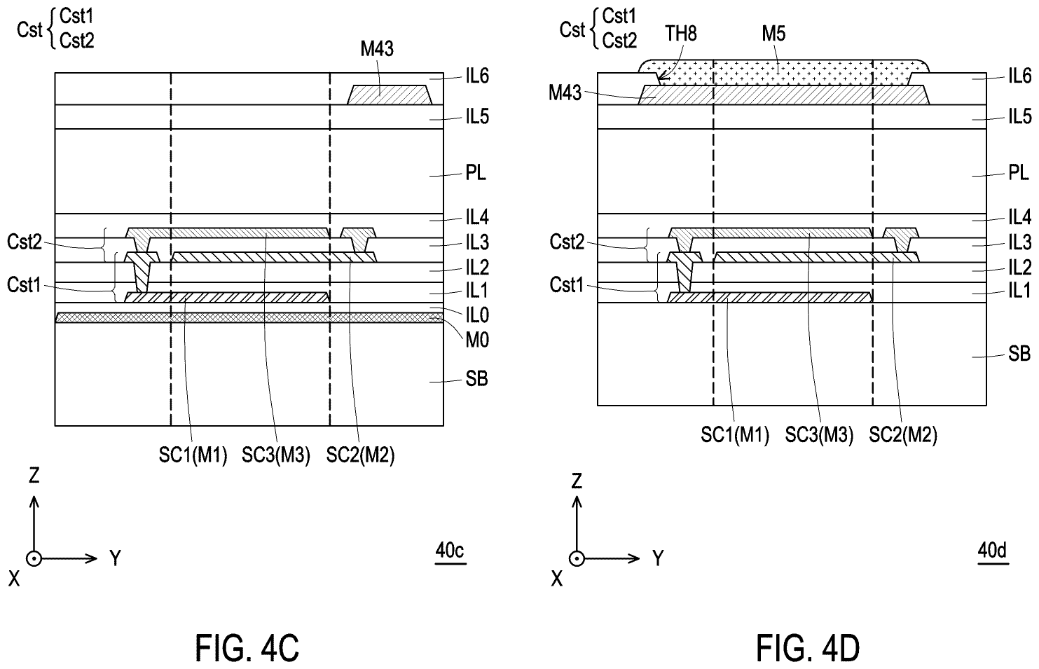

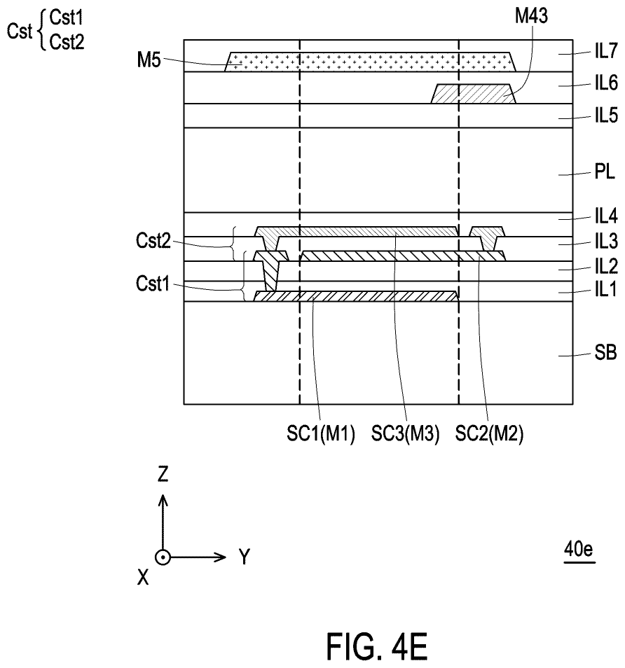

The conductive layer M1 is, for instance, disposed on the substrate SB and may act as a light-shielding layer and/or a storage electrode (for instance, a storage electrode SC1 shown in FIG. 4A to FIG. 4E). In some embodiments, a portion of the conductive layer M1 may also serve as a gate of a transistor and be located below the semiconductor layers SE1 and SE2. Specifically, in this embodiment, the conductive layer M1 is disposed on the substrate SB, and is at least located between the substrate SB and a channel region of the first semiconductor layer SE1 and a channel region of the second semiconductor layer SE2, thereby reducing the degradation of the channel region due to exposure to ambient light. In some embodiments, a material of the conductive layer M1 may include a material with a transmittance less than 30%, which should however not be construed as a limitation in the disclosure.

The insulating layer IL1 is, for instance, disposed on the substrate SB. In this embodiment, the insulating layer IL1 partially covers the conductive layer M1. Specifically, the insulating layer IL1 includes a through-hole that exposes a portion of the conductive layer M1, which should however not be construed as a limitation in the disclosure. A material of the insulating layer IL1 may include, for instance, an inorganic material (e.g., silicon oxide, silicon nitride, silicon oxynitride, or a stacked layer containing at least two of the above materials), which should however not be construed as a limitation in the disclosure.

The insulating layer IL2 is, for instance, disposed on the insulating layer IL1. In this embodiment, the first semiconductor layer SE1 and the second semiconductor layer SE2 may be disposed between the insulating layer IL2 and the insulating layer ILL. The insulating layer IL2, for instance, partially covers the first semiconductor layer SE1 and the second semiconductor layer SE2. Specifically, the insulating layer IL2 includes a through-hole that exposes a portion of the first semiconductor layer SE1 and a portion of the second semiconductor layer SE2, which should however not be construed as a limitation in the disclosure. Besides, the insulating layer IL2 further includes a through-hole that exposes a portion of the conductive layer M1. Specifically, the through-hole in the insulating layer IL2 may communicate with the through-hole in the insulating layer IL1 to collectively form a through-hole TH1 that exposes a portion of the conductive layer M1. A material of the insulating layer IL2 may include, for instance, an inorganic material (e.g., silicon oxide, silicon nitride, silicon oxynitride, or a stacked layer containing at least two of the above materials), which should however not be construed as a limitation in the disclosure.

The conductive layer M2 is, for instance, disposed on the insulating layer IL. In this embodiment, the conductive layer M2 may include a storage electrode SC2 and a gate G. In some embodiments, the storage electrode SC2 may be electrically connected to the conductive layer M1 through the through-hole TH1 that penetrates the insulating layer IL1 and the insulating layer IL2, which should however not be construed as a limitation in the disclosure. The gate G, for instance, at least partially overlaps the first semiconductor layer SE1 of the first transistor T1 and the second semiconductor layer SE2 of the second transistor T2 in the normal direction Z of the substrate SB.

The insulating layer IL3 is, for instance, disposed on the insulating layer IL2. In this embodiment, the insulating layer IL3 partially covers the first semiconductor layer SE1 and the second semiconductor layer SE2. Specifically, the insulating layer IL3 includes through-holes that expose a portion of the first semiconductor layer SE1 and a portion of the second semiconductor layer SE2, where the through-holes in the insulating layer IL3 may communicate with the through-holes in the insulating layer IL2 to form through-holes TH2 and TH3, thereby exposing the portion of the first semiconductor layer SE1 and the portion of the second semiconductor layer SE2. A material of the insulating layer IL3 may include, for instance, an inorganic material (e.g., silicon oxide, silicon nitride, silicon oxynitride, or a stacked layer containing at least two of the above materials), which should however not be construed as a limitation in the disclosure.

The conductive layer M3 is, for instance, disposed on the insulating layer IL3. In this embodiment, the conductive layer M3 may include a source S, a drain D, a third power line VDD′, and a fourth power line VSS′. The source S is, for instance, separated from the drain D, where the source S may be electrically connected to the first semiconductor layer SE1 or the second semiconductor layer SE2 through the through-hole TH2 that penetrates the insulating layers IL2 and IL3, and the drain D may be electrically connected to the first semiconductor layer SE1 or the second semiconductor layer SE2 through the through-hole TH3 that penetrates the insulating layers IL2 and IL3, which should however not be construed as a limitation in the disclosure. The third power line VDD′, for instance, extends along the second direction X and may be configured to provide a first power voltage to the first light-emitting unit LE1 and the second light-emitting unit LE2. The fourth power line VSS′, for instance, extends along the second direction X and may be configured to provide a second power voltage to the first light-emitting unit LE1 and the second light-emitting unit LE2, where a voltage level of the second power voltage is less than a voltage level of the first power voltage.

The insulating layer IL4 is, for instance, disposed on the insulating layer IL3. In this embodiment, the insulating layer IL4 partially covers the drain D, the third power line VDD′, and the fourth power line VSS′. Specifically, the insulating layer IL4 includes a plurality of through-holes, each of which partially exposes the drain D, the third power line VDD′, and the fourth power line VSS′. A material of the insulating layer IL4 may be an inorganic material (e.g., silicon oxide, silicon nitride, silicon oxynitride, or a stacked layer containing at least two of the above materials), which should however not be construed as a limitation in the disclosure.

The planarization layer PL is, for instance, disposed on the insulating layer IL4. In this embodiment, the planarization layer PL also partially covers the drain D, the third power line VDD′, and the fourth power line VSS′. Specifically, the planarization layer PL also includes a plurality of through-holes, each of which partially exposes the drain D, the third power line VDD′, and the fourth power line VSS′. A material of the planarization layer PL may be an organic material (e.g., PI resin, epoxy resin, or acrylic resin) or a combination of the above, which should however not be construed as a limitation in the disclosure.

The insulating layer IL5 is, for instance, disposed on the planarization layer PL. In this embodiment, the insulating layer IL5 also partially covers the drain D, the third power line VDD′, and the fourth power line VSS′. Specifically, the insulating layer IL5 also includes a plurality of through-holes, each of which partially exposes the drain D, the third power line VDD′, and the fourth power line VSS′. The through-holes in the insulating layer IL5 may communicate with the through-holes in the planarization layer PL and the through-holes in the insulating layer IL4 to form through-holes TH4, TH5 (shown in FIG. 2A), and TH6, each partially exposing the drain D, the third power line VDD′, and the fourth power line VSS′. A material of the insulating layer IL5 may be an inorganic material (e.g., silicon oxide, silicon nitride, silicon oxynitride, or a stacked layer containing at least two of the above materials), which should however not be construed as a limitation in the disclosure.

The conductive layer M4 is, for instance, disposed on the insulating layer IL5. In this embodiment, the conductive layer M4 includes the pad patterns P1 and P2, the first power line VDD, and the second power line VSS. The pad pattern P1 may, for instance, be electrically connected to the drain D through the through-hole TH4 that penetrates the insulating layer IL4, the planarization layer PL, and the insulating layer IL5, and the pad pattern P2 may, for instance, be connected to the second power line VSS. The first power line VDD may, for instance, extend along the second direction X and may be electrically connected to the first power line VDD′ through the through-hole TH5 that penetrates the insulating layer IL4, the planarization layer PL, and the insulating layer IL5. The second power line VSS may, for instance, extend along the second direction X and may be electrically connected to the second power line VSS' through the through-hole TH6 that penetrates the insulating layer IL4, the planarization layer PL, and the insulating layer IL5.

The insulating layer IL6 is, for instance, disposed on the insulating layer IL5. In this embodiment, the insulating layer IL6 partially covers the pad patterns P1 and P2. Specifically, the insulating layer IL6 includes through-holes TH7 and TH7′. As previously mentioned, the range of the pad patterns P1 and P2 is defined as a portion of the conductive layer M that is exposed by through holes TH7 and TH7′. A material of the insulating layer IL6 may, for instance, be an inorganic material (e.g., silicon oxide, silicon nitride, silicon oxynitride, or a stacked layer containing at least two of the above materials), which should however not be construed as a limitation in the disclosure.

The bonding structure BS is, for instance, disposed on the insulating layer IL6. In this embodiment, the bonding structure BS may be electrically connected to the pad pattern P1 through the through-hole TH7 and may be electrically connected to the pad pattern P2 through the through-hole TH7′. In some embodiments, the bonding structure BS may include a bonding layer BS1 and a bonding layer BS2, where the bonding layer BS1 is disposed on the bonding layer BS2, and a portion of the bonding layer BS2 is disposed in the through-holes TH7 and TH7′ to be electrically connected to the pad patterns P1 and P2, respectively, which should however not be construed as a limitation in the disclosure. In some embodiments, the bonding structure BS may include solder materials, bumps, solder balls, conductive pillars, other suitable structures, or a combination thereof, which should however not be construed as a limitation in the disclosure. A material of the bonding structure BS may, for instance, include metal or alloy. For instance, a material of the bonding layer BS1 may include tin, and a material of the bonding layer BS2 may include nickel, which should however not be construed as a limitation in the disclosure.

As may be understood from the previous description, note that the driving circuit in one pixel region may include a plurality of driving transistors. In this embodiment, a pixel region may include another driving transistor (not shown) that is electrically connected to the driving transistor T1 or T2 shown in FIG. 2B, and the first power line VDD may be electrically connected to the another driving transistor through a through-hole TH0. In some embodiments, the first power line VDD may be directly electrically connected to the driving transistor T1 or T2 shown in FIG. 2B through the through-hole TH0.

The first light-emitting unit LE1 and the second light-emitting unit LE2 are, for instance, disposed on the insulating layer IL6, each of which is electrically connected to the bonding structure BS. Accordingly, the first light-emitting unit LE1 and the second light-emitting unit LE2 may receive the driving current (generated by the power voltage transmitted to the driving transistor through the electrical connection relationship described earlier between the third power line VDD′ and the first power line VDD) from the driving transistor (i.e., the first transistor T1 and the second transistor T2 in this embodiment) through the bonding structure BS and the pad pattern P1, and the first light-emitting unit LE1 and the second light-emitting unit LE2 may receive a ground voltage through the bonding structure BS, the pad pattern P2, the second power line VSS, and the fourth power line VSS′. In some embodiments, the brightness of the first light-emitting unit LE1 and the second light-emitting unit LE2 may correspond to the intensity of the driving current from the driving transistor.

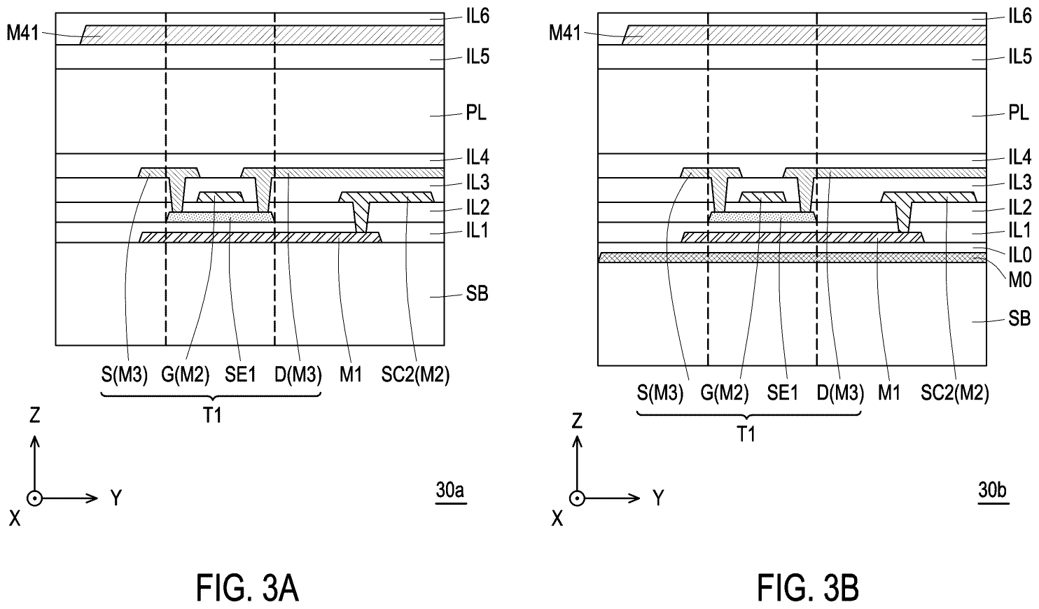

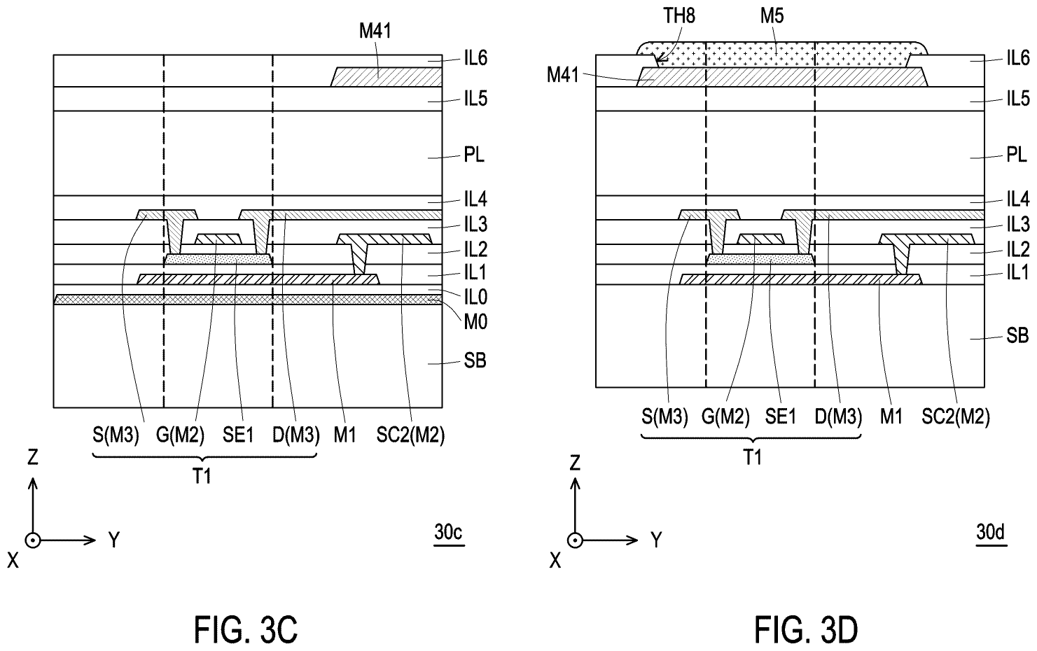

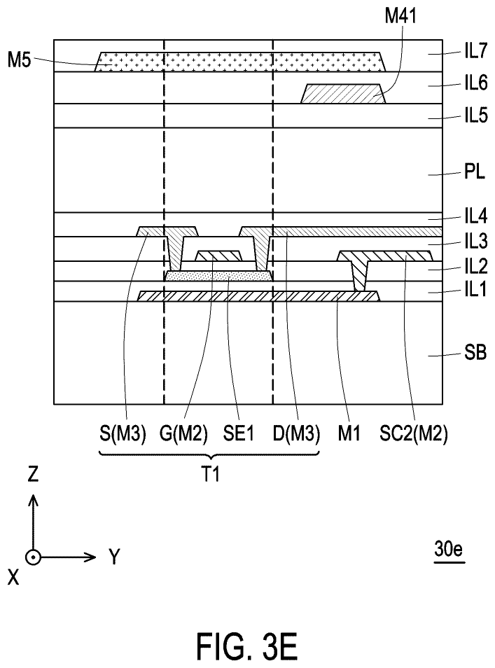

FIG. 3A is a schematic partial cross-sectional view illustrating an arrangement relationship between a first semiconductor layer and a conductive layer in an electronic device according to a first embodiment of the disclosure. FIG. 3B is a schematic partial cross-sectional view illustrating an arrangement relationship between a first semiconductor layer and a conductive layer in an electronic device according to a second embodiment of the disclosure. FIG. 3C is a schematic partial cross-sectional view illustrating an arrangement relationship between a first semiconductor layer and a conductive layer in an electronic device according to a third embodiment of the disclosure. FIG. 3D is a schematic partial cross-sectional view illustrating an arrangement relationship between a first semiconductor layer and a conductive layer in an electronic device according to a fourth embodiment of the disclosure. FIG. 3E is a schematic partial cross-sectional view illustrating an arrangement relationship between a first semiconductor layer and a conductive layer in an electronic device according to a fifth embodiment of the disclosure. It should be noted that the reference numbers and some content provided in the embodiments shown in FIG. 3A to FIG. 3E may be derived from the reference numbers and some content provided in the embodiments shown in FIG. 2A and FIG. 2B, where the same or similar reference numbers serve to represent the same or similar components, and the description of the same technical content is omitted.

With reference to FIG. 3A, in an electronic device 30a provided in this embodiment, the first semiconductor layer SE1 completely overlaps the first portion M41 of the conductive layer M4 in the normal direction Z of the substrate SB. In addition, although not shown in FIG. 3A, the second semiconductor layer SE2 may also at least partially overlap the second portion M42 of the conductive layer M4 in the normal direction Z of the substrate SB.

Accordingly, the conductive layer M4 may shield the first semiconductor layer SE1 and the second semiconductor layer SE2 that have been formed in the process of forming the electronic device 30a, thereby reducing the possibility of defects generated in the first semiconductor layer SE1 and the second semiconductor layer SE2.

With reference to FIG. 3B, the main difference between an electronic device 30b provided in this embodiment and the electronic device 30a provided above lies in that the electronic device 30b further includes an insulating layer IL0 and a conductive layer M0.

For instance, the insulating layer IL0 may be disposed between the substrate SB and the conductive layer M1. A material of the insulating layer IL0 may include, for instance, an inorganic material (such as silicon oxide, silicon nitride, silicon oxynitride, or a stacked layer containing at least two of the above materials), which should however not be construed as a limitation in the disclosure.

For instance, the conductive layer M0 may be disposed between the substrate SB and the insulating layer IL0 and is covered by the insulating layer IL0. In this embodiment, the conductive layer M0 is located between the first semiconductor layer SE1 and the substrate SB. In some embodiments, the first semiconductor layer SE1 at least partially overlaps the conductive layer M0 in the normal direction Z of the substrate SB. In this embodiment, the first semiconductor layer SE1 completely overlaps the conductive layer M0 in the normal direction Z of the substrate SB. Additionally, although not shown in FIG. 3B, the second semiconductor layer SE2 may also at least partially overlap the conductive layer M0 in the normal direction Z of the substrate SB. That is, similar to the conductive layer M4, the conductive layer M0 may also be divided into two connected parts, one of which at least partially overlaps the first semiconductor layer SE1, and the other of which overlaps the second semiconductor layer SE2. In some embodiments, the conductive layer M0 may be floating or may receive a corresponding signal (for instance, receiving a ground signal for electromagnetic shielding), which should however not be construed as a limitation in the disclosure. In this embodiment, the conductive layer M0 is the bottommost conductive layer in the electronic device 30b, which should however not be construed as a limitation in the disclosure.

Accordingly, the conductive layer M0 may, together with the conductive layer M4, shield the first semiconductor layer SE1 and the second semiconductor layer SE2 that have been formed in the process of forming the electronic device 30b, thereby reducing the possibility of defects generated in the first semiconductor layer SE1 and the second semiconductor layer SE2.

With reference to FIG. 3C, the main difference between an electronic device 30c provided in this embodiment and the electronic device 30b provided above lies in that the first semiconductor layer SE1 and the second semiconductor layer SE2 of the electronic device 30c completely overlap the conductive layer M0 in the normal direction Z of the substrate SB but do not overlap the conductive layer M4.

Accordingly, the conductive layer M0 may shield the first semiconductor layer SE1 and the second semiconductor layer SE2 that have been formed in the process of forming the electronic device 30c, thereby reducing the possibility of defects generated in the first semiconductor layer SE1 and the second semiconductor layer SE2.

With reference to FIG. 3D, the main difference between an electronic device 30d provided in this embodiment and the electronic device 30a provided above lies in that the electronic device 30d further includes a conductive layer M5.

The conductive layer M5 is, for instance, disposed on the insulating layer IL6 and may be electrically connected to the conductive layer M41 through a through hole TH8 penetrating the insulating layer IL6, for instance. In some embodiments, the first semiconductor layer SE1 at least partially overlaps the conductive layer M5 in the normal direction Z of the substrate SB. In this embodiment, the first semiconductor layer SE1 completely overlaps the conductive layer M5 in the normal direction Z of the substrate SB. In addition, although not shown in FIG. 3D, the second semiconductor layer SE2 may also at least partially overlap the conductive layer M5 in the normal direction Z of the substrate SB.

Accordingly, the conductive layer M5 may, together with the conductive layer M4, shield the first semiconductor layer SE1 and the second semiconductor layer SE2 that have been formed in the process of forming the electronic device 30d, thereby reducing the possibility of defects generated in the first semiconductor layer SE1 and the second semiconductor layer SE2.

With reference to FIG. 3E, the main difference between an electronic device 30e provided in this embodiment and the electronic device 30c provided above lies in that the electronic device 30e includes a conductive layer M5 but does not include a conductive layer M0.

The conductive layer M5 is, for instance, disposed on the insulating layer IL6. In some embodiments, the first semiconductor layer SE1 at least partially overlaps the conductive layer M5 in the normal direction Z of the substrate SB. In this embodiment, the first semiconductor layer SE1 completely overlaps the conductive layer M5 in the normal direction Z of the substrate SB. In addition, although not shown in FIG. 3E, the second semiconductor layer SE2 may also at least partially overlap the conductive layer M5 in the normal direction Z of the substrate SB. In some embodiments, the conductive layer M5 is floating, which should however not be construed as a limitation in the disclosure.

In this embodiment, the electronic device 30e further includes an insulating layer IL7. The insulating layer IL7 is, for instance, disposed on the conductive layer M5 and may cover the conductive layer M5. A material of the insulating layer IL7 may include, for instance, an inorganic material (such as silicon oxide, silicon nitride, silicon oxynitride, or a stacked layer containing at least two of the above materials), which should however not be construed as a limitation in the disclosure.

Accordingly, the conductive layer M5 may shield the first semiconductor layer SE1 and the second semiconductor layer SE2 that have been formed in the process of forming the electronic device 30e, thereby reducing the possibility of defects generated in the first semiconductor layer SE1 and the second semiconductor layer SE2.

FIG. 4A is a schematic partial cross-sectional view illustrating an arrangement relationship between a storage capacitor and the conductive layer in the electronic device according to the first embodiment of the disclosure. FIG. 4B is a schematic partial cross-sectional view illustrating an arrangement relationship between a storage capacitor and the conductive layer in the electronic device according to the second embodiment of the disclosure. FIG. 4C is a schematic partial cross-sectional view illustrating an arrangement relationship between a storage capacitor and the conductive layer in the electronic device according to the third embodiment of the disclosure. FIG. 4D is a schematic partial cross-sectional view illustrating an arrangement relationship between a storage capacitor and the conductive layer in the electronic device according to the fourth embodiment of the disclosure. FIG. 4E is a schematic partial cross-sectional view illustrating an arrangement relationship between a storage capacitor and the conductive layer in the electronic device according to the fifth embodiment of the disclosure. It should be noted that the reference numbers and some content provided in the embodiments shown in FIG. 4A to FIG. 3E may be derived from the reference numbers and some content provided in the embodiments shown in FIG. 2A and FIG. 2B, where the same or similar reference numbers serve to represent the same or similar components, and the description of the same technical content is omitted.

With reference to FIG. 4A, in an electronic device 40a provided in this embodiment, the storage capacitor Cst includes two parallel capacitors Cst1 and Cst2, where the capacitor Cst1 is formed by the storage electrode SC1 included in the conductive layer M1, the storage electrode SC2 included in the conductive layer M2, and the insulating layer disposed therebetween, and the capacitor Cst2 is formed by the storage electrode SC2 included in the conductive layer M2, the storage electrode SC3 included in the conductive layer M3, and the insulating layer disposed therebetween. However, the structure of the storage capacitor Cst in the disclosure should not be construed as a limitation.

In this embodiment, the conductive layer M4 further includes a third portion M43, and in the normal direction N of the substrate SB, the third portion M43 at least partially overlaps the storage capacitor Cst. In this embodiment, the storage capacitor Cst completely overlaps the conductive layer M4 in the normal direction Z of the substrate SB.

Accordingly, the conductive layer M4 may shield the storage capacitor Cst that has been formed in the process of forming the electronic device 40a, thereby reducing the possibility of defects generated in the storage capacitor Cst.

With reference to FIG. 4B, the main difference between an electronic device 40b provided in this embodiment and the electronic device 40a provided above lies in that the electronic device 40b further includes an insulating layer IL0 and a conductive layer M0. The storage capacitor Cst may at least partially overlap the conductive layer M0 in the normal direction Z of the substrate SB. For instance, in this embodiment, the storage capacitor Cst completely overlaps the conductive layer M0 in the normal direction Z of the substrate SB. The insulating layer IL0 and the conductive layer M0 in this embodiment may be the same as or similar to the insulating layer IL0 and the conductive layer M0 provided in the embodiment as illustrated in FIG. 3B and thus will no longer be described hereinafter.

Accordingly, the conductive layer M0 may, together with the conductive layer M4, shield the storage capacitor Cst that has been formed in the process of forming the electronic device 40b, thereby reducing the possibility of defects generated in the storage capacitor Cst.

With reference to FIG. 4C, the main difference between an electronic device 40c provided in this embodiment and the electronic device 40b provided above lies in that the storage capacitor Cst of the electronic device 40c completely overlaps the conductive layer M0 in the normal direction Z of the substrate SB but does not overlap the conductive layer M4.

Accordingly, the conductive layer M0 may shield the storage capacitor Cst that has been formed in the process of forming the electronic device 40c, thereby reducing the possibility of defects generated in the storage capacitor Cst.

With reference to FIG. 4D, the main difference between an electronic device 40d provided in this embodiment and the electronic device 40a provided above lies in that the electronic device 40d further includes a conductive layer M5.

The conductive layer M5 is, for instance, disposed on the insulating layer IL6 and may be electrically connected to the conductive layer M4 through a through hole TH8 penetrating the insulating layer IL6, for instance. In some embodiments, the storage capacitor Cst at least partially overlaps the conductive layer M5 in the normal direction Z of the substrate SB. In this embodiment, the storage capacitor Cst completely overlaps the conductive layer M5 in the normal direction Z of the substrate SB.

Accordingly, the conductive layer M5 may, together with the conductive layer M4, shield the storage capacitor Cst that has been formed in the process of forming the electronic device 40d, thereby reducing the possibility of defects generated in the storage capacitor Cst.

With reference to FIG. 4E, the main difference between an electronic device 40e provided in this embodiment and the electronic device 40c provided above lies in that the electronic device 40e includes a conductive layer M5 but does not include a conductive layer M0.

The conductive layer M5 is, for instance, disposed on the insulating layer IL6. In some embodiments, the storage capacitor Cst at least partially overlaps the conductive layer M5 in the normal direction Z of the substrate SB. In this embodiment, the storage capacitor Cst completely overlaps the conductive layer M5 in the normal direction Z of the substrate SB. In some embodiments, the conductive layer M5 is floating, which should however not be construed as a limitation in the disclosure.

In this embodiment, the electronic device 40e further includes an insulating layer IL7. The insulating layer IL7 is, for instance, disposed on the conductive layer M5 and may cover the conductive layer M5. A material of the insulating layer IL7 may include, for instance, an inorganic material (such as silicon oxide, silicon nitride, silicon oxynitride, or a stacked layer containing at least two of the above materials), which should however not be construed as a limitation in the disclosure.

Accordingly, the conductive layer M5 may shield the storage capacitor Cst that has been formed in the process of forming the electronic device 40e, thereby reducing the possibility of defects generated in the storage capacitor Cst.

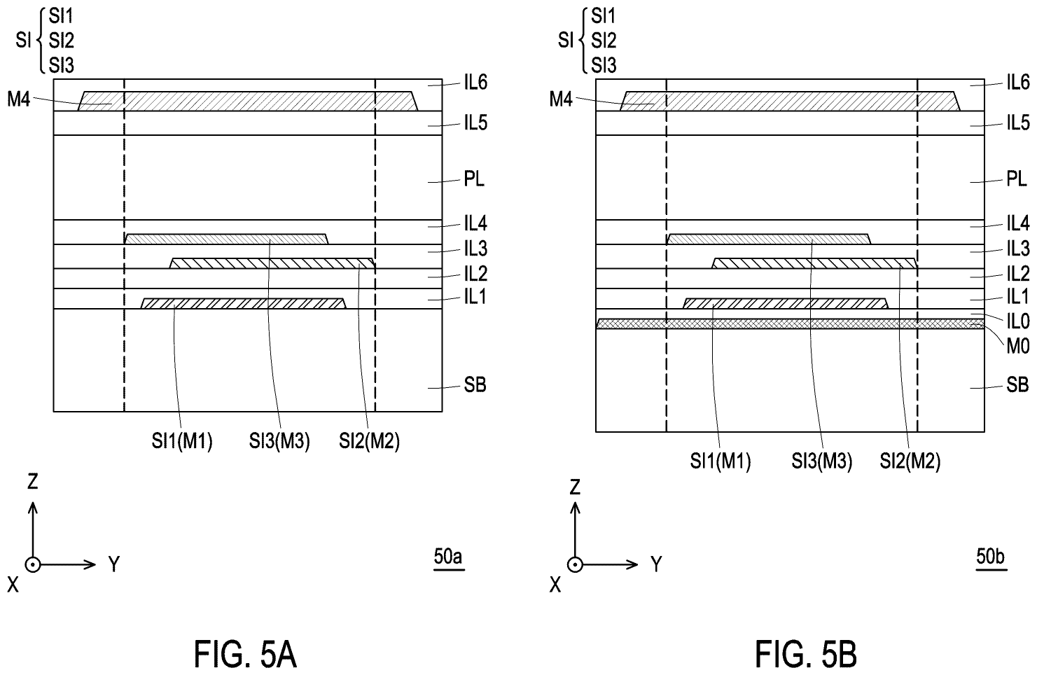

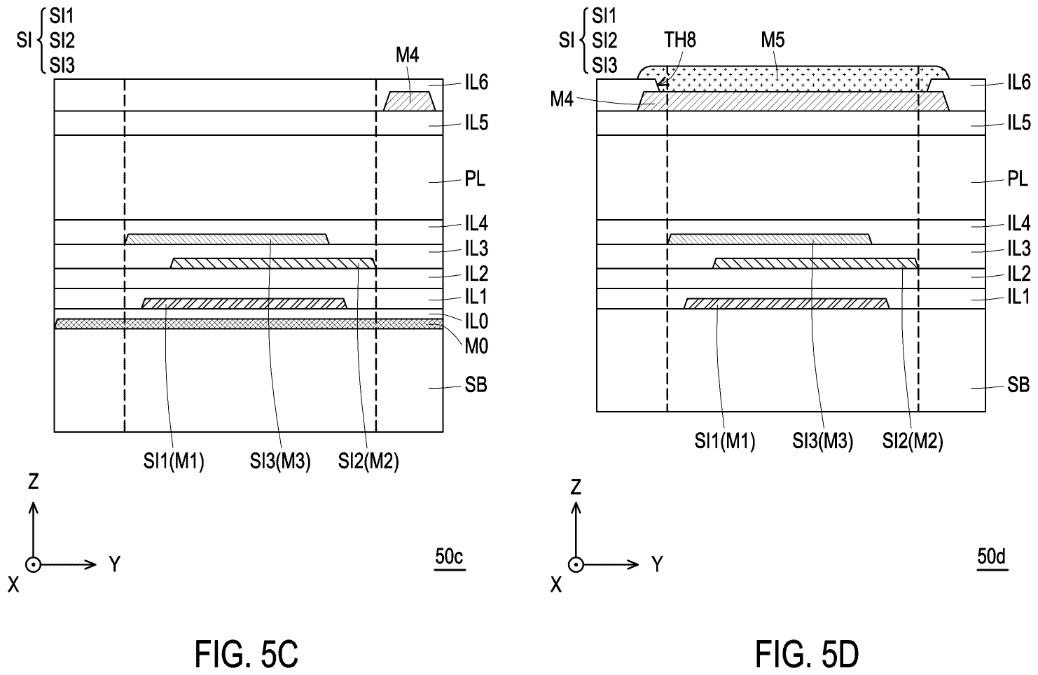

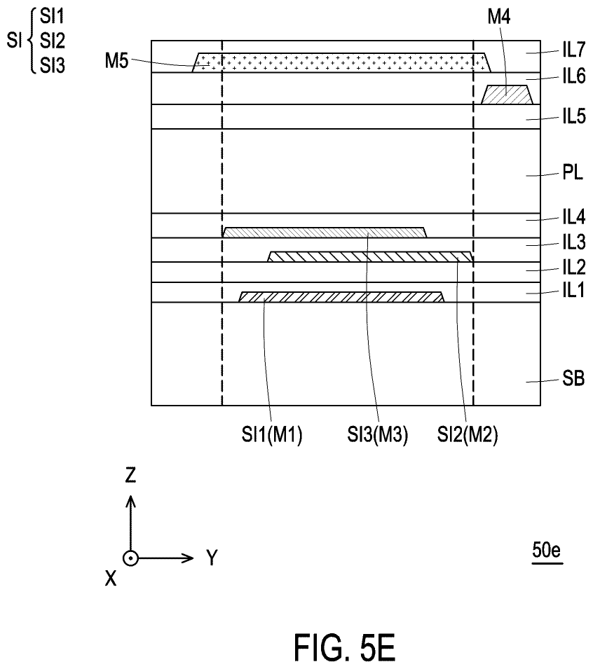

FIG. 5A is a schematic partial cross-sectional view illustrating an arrangement relationship between a signal line and the conductive layer in the electronic device according to the first embodiment of the disclosure. FIG. 5B is a schematic partial cross-sectional view illustrating an arrangement relationship between a signal line and the conductive layer in the electronic device according to the second embodiment of the disclosure. FIG. 5C is a schematic partial cross-sectional view illustrating an arrangement relationship between a signal line and the conductive layer in the electronic device according to the third embodiment of the disclosure. FIG. 5D is a schematic partial cross-sectional view illustrating an arrangement relationship between a signal line and the conductive layer in the electronic device according to the fourth embodiment of the disclosure. FIG. 5E is a schematic partial cross-sectional view illustrating an arrangement relationship between a signal line and the conductive layer in the electronic device according to fifth first embodiment of the disclosure. It should be noted that the reference numbers and some content provided in the embodiments shown in FIG. 5A to FIG. 3E may be derived from the reference numbers and some content provided in the embodiments shown in FIG. 2A and FIG. 2B, where the same or similar reference numbers serve to represent the same or similar components, and the description of the same technical content is omitted.

With reference to FIG. 5A, in an electronic device 50a provided in this embodiment, the signal line SI may be formed by a signal line SI1 included in the conductive layer M1, a signal line SI2 included in the conductive layer M2, and/or a signal line SI3 included in the conductive layer M3, which should however not be construed as a limitation in the disclosure. In addition, the signal line SI may include the above-mentioned scan lines SL, data lines DL′, and/or other suitable signal lines, which should however not be construed as a limitation in the disclosure.

The signal line SI may, for instance, at least partially overlap the conductive layer M4 in the normal direction Z of the substrate SB. In this embodiment, the signal line SI completely overlaps the conductive layer M4 in the normal direction Z of the substrate SB.

Accordingly, the conductive layer M4 may shield the signal line SI that has been formed in the process of forming the electronic device 50a, thereby reducing the possibility of defects generated in the signal line SI.

With reference to FIG. 5B, the main difference between an electronic device 50b provided in this embodiment and the electronic device 50a provided above lies in that the electronic device 50b further includes an insulating layer IL0 and a conductive layer M0. In some embodiments, the signal line SI may at least partially overlap the conductive layer M0 in the normal direction Z of the substrate SB. In this embodiment, the signal line SI completely overlaps the conductive layer M0 in the normal direction Z of the substrate SB. The insulating layer IL0 and the conductive layer M0 in this embodiment may be the same as or similar to the insulating layer IL0 and the conductive layer M0 provided in the embodiment as shown in FIG. 3B and thus will no longer be described hereinafter.

Accordingly, the conductive layer M0 may, together with the conductive layer M4, shield the signal line SI that has been formed in the process of forming the electronic device 50b, thereby reducing the possibility of defects generated in the signal line SI.

With reference to FIG. 5C, the main difference between an electronic device 50c provided in this embodiment and the electronic device 50b provided above lies in that the signal line SI of the electronic device 50c completely overlaps the conductive layer M0 in the normal direction Z of the substrate SB but does not overlap the conductive layer M4.

Accordingly, the conductive layer M0 may shield the signal line SI that has been formed in the process of forming the electronic device 50c, thereby reducing the possibility of defects generated in the signal line SI.

With reference to FIG. 5D, the main difference between an electronic device 50d provided in this embodiment and the electronic device 50a provided above lies in that the electronic device 50d further includes a conductive layer M5.

For instance, the conductive layer M5 is disposed on the insulating layer IL6 and may be electrically connected to the conductive layer M4 through the through hole TH8 penetrating the insulating layer IL6. In some embodiments, the signal line SI may at least partially overlap the conductive layer M5 in the normal direction Z of the substrate SB. In this embodiment, the signal line SI completely overlaps the conductive layer M5 in the normal direction Z of the substrate SB.

Accordingly, the conductive layer M5 may, together with the conductive layer M4, shield the signal line SI that has been formed in the process of forming the electronic device 50d, thereby reducing the possibility of defects generated in the signal line SI.

With reference to FIG. 5E, the main difference between an electronic device 50e provided in this embodiment and the electronic device 50c provided above lies in that the electronic device 50e includes a conductive layer M5 but does not include a conductive layer M0.

For instance, the conductive layer M5 is disposed on the insulating layer IL6. In some embodiments, the signal line SI may at least partially overlap the conductive layer M5 in the normal direction Z of the substrate SB. In this embodiment, the signal line SI completely overlaps the conductive layer M5 in the normal direction Z of the substrate SB. In some embodiments, the conductive layer M5 is floating, which should however not be construed as a limitation in the disclosure.

In this embodiment, the electronic device 50e further includes an insulating layer IL7. For instance, the insulating layer IL7 is disposed on the conductive layer M5 and may cover the conductive layer M5. A material of the insulating layer IL7 may include, for instance, an inorganic material (such as silicon oxide, silicon nitride, silicon oxynitride, or a stacked layer containing at least two of the above materials), which should however not be construed as a limitation in the disclosure.

Accordingly, the conductive layer M5 may shield the signal line SI that has been formed in the process of forming the electronic device 50e, thereby reducing the possibility of defects generated in the signal line SI. In this disclosure, note that the conductive layer configured to shield the semiconductor layer, the storage capacitor, and the signal line in the electronic device is not in the same layer as the semiconductor layer, the storage capacitor, and the signal line in the electronic device.

To sum up, in the electronic device provided in one or more embodiments of the disclosure, the ratio of the first area occupied by the conductive layer disposed in the pixel regions to the second area occupied by the pixel regions is set to be greater than or equal to 50% and less than or equal to 100%. This allows the components that have already been formed in the pixel regions (such as the first semiconductor layer, the second semiconductor layer, the storage capacitor, and/or the signal line or other suitable components) to be at least partially shielded by the conductive layer in the process of forming the remaining components, thereby reducing the possibility of defect generation. As such, the electronic device in one or more embodiments of the disclosure may have an improved yield.

Although the embodiments of the disclosure and the advantages thereof have been disclosed above, it should be understood that any person skilled in the art can make changes, substitutions, and modifications without departing from the spirit and scope of the disclosure, and the features of the embodiments can be arbitrarily mixed and replaced to form other new embodiments. In addition, the protection scope of the disclosure is not limited to the process, machine, manufacture, material composition, device, method, and steps in the specific embodiments described in the specification. Any person skilled in the art can understand conventional or future-developed processes, machines, manufactures, material compositions, devices, methods, and steps from the content of the disclosure as long as the same can implement substantially the same functions or achieve substantially the same results in the embodiments described herein. Therefore, the protection scope of the disclosure includes the above processes, machines, manufactures, material compositions, devices, methods, and steps. In addition, each claim constitutes a separate embodiment, and the protection scope of the disclosure further includes combinations of the claims and the embodiments. The protection scope of the disclosure should be defined by the appended claims.

What is claimed is:

1. An electronic device, comprising:
a substrate;
a first light-emitting unit and a second light-emitting unit, disposed on the substrate;
a first driving circuit, disposed on the substrate and comprising a first transistor configured to drive the first light-emitting unit;
a second driving circuit, disposed on the substrate and comprising a second transistor configured to drive the second light-emitting unit; and
a conductive layer, disposed between the substrate and the first light-emitting unit and between the substrate and the second light-emitting unit and comprising a first portion and a second portion connected to the first portion,
wherein the first transistor comprises a first semiconductor layer, the second transistor comprises a second semiconductor layer, and in a normal direction of the substrate, the first portion at least partially overlaps the first semiconductor layer, and the second portion at least partially overlaps the second semiconductor layer.

2. The electronic device according to claim 1, wherein in the normal direction of the substrate, the first semiconductor layer completely overlaps the first portion.

3. The electronic device according to claim 1, wherein in the normal direction of the substrate, the second semiconductor layer completely overlaps the second portion.

4. The electronic device according to claim 1, wherein in the normal direction of the substrate, the conductive layer is located between the first semiconductor layer and the substrate.

5. The electronic device according to claim 1, wherein in the normal direction of the substrate, the conductive layer is located between the first semiconductor layer and the first light-emitting unit.

6. The electronic device according to claim 5, further comprising a first power line and a second power line extending in a first direction.

7. The electronic device according to claim 6, further comprising a third power line and a fourth power line extending in a second direction, wherein the second direction is different from the first direction.

8. The electronic device according to claim 7, wherein pixel regions of the electronic device are defined by the first power line and the second power line and defined by the third power line and the fourth power line.

9. The electronic device according to claim 1, wherein at least one of the first driving circuit and the second driving circuit comprises a capacitor, the conductive layer further comprises a third portion, and in the normal direction of the substrate, the third portion at least partially overlaps the capacitor.

10. The electronic device according to claim 1, wherein the first transistor comprises a switch transistor, a driving transistor, or both.

11. The electronic device according to claim 1, wherein the second transistor comprises a switch transistor, a driving transistor, or both.

12. An electronic device, comprising:
a substrate, comprising a plurality of pixel regions;
a first light-emitting unit, disposed on the substrate and located in one of the pixel regions;
a first driving circuit, disposed on the substrate and configured to drive the first light-emitting unit, wherein the first driving circuit is located in the one of the pixel regions; and
a conductive layer, disposed between the substrate and the first light-emitting unit, wherein at least one portion of the conductive layer is located in the one of the pixel regions,
wherein in a top view of the electronic device, the at least one portion of the conductive layer located in the one of the pixel regions occupies a first area, and a ratio of the first area to a second area occupied by the pixel regions is greater than or equal to 50% and less than or equal to 100%.

13. The electronic device according to claim 12, wherein the first driving circuit comprises a first transistor, the first transistor comprises a first semiconductor layer, and in a normal direction of the substrate, the conductive layer at least partially overlaps the first semiconductor layer.

14. The electronic device according to claim 13, wherein the first transistor comprises a switch transistor, and a ratio of an overlapping area of the first semiconductor layer of the first transistor and the conductive layer in the normal direction of the substrate to a third area occupied by the first transistor is greater than or equal to 50% and less than or equal to 100%.

15. The electronic device according to claim 13, wherein the first transistor comprises a driving transistor, and a ratio of an overlapping area of the first semiconductor layer of the first transistor and the conductive layer in the normal direction of the substrate to a fourth area occupied by the first transistor is greater than or equal to 50% and less than or equal to 100%.

16. The electronic device according to claim 12, wherein the first driving circuit comprises a capacitor, and in a normal direction of the substrate, the conductive layer at least partially overlaps the capacitor.

17. The electronic device according to claim 16, wherein a ratio of an overlapping area of the capacitor and the conductive layer in the normal direction of the substrate to a fifth area occupied by the capacitor is greater than or equal to 50% and less than or equal to 100%.

18. The electronic device according to claim 12, further comprising a signal line, wherein a ratio of an overlapping area of the signal line and the conductive layer in a normal direction of the substrate to a sixth area occupied by the signal line is greater than or equal to 50% and less than or equal to 100%.

19. The electronic device according to claim 12, wherein the first driving circuit comprises a first transistor, the first transistor comprises a first semiconductor layer, and in a normal direction of the substrate, the conductive layer is located between the first semiconductor layer and the substrate.

20. The electronic device according to claim 12, wherein the first driving circuit comprises a first transistor, the first transistor comprises a first semiconductor layer, and in a normal direction of the substrate, the conductive layer is located between the first semiconductor layer and the first light-emitting unit.
